(19) United States
(12) Patent Application Publication
(10) Pub. No.: US 2025/0364485 A1
(43) Pub. Date: Nov. 27, 2025

(54) DICING MULTI-DIE MEMORY STACKS

(71) Applicant: Micron Technology, Inc., Boise, ID (US)

(72) Inventors: Bharat Bhushan, Boise, ID (US); Wei Zhou, Boise, ID (US); Kunal R. Parekh, Boise, ID (US); Akshay N. Singh, Boise, ID (US)

(21) Appl. No.: 19/212,227

(22) Filed: May 19, 2025

Related U.S. Application Data
(60) Provisional application No. 63/651,879, filed on May 24, 2024.

(51) Int. Cl. H01L 23/00; H01L 25/00; H01L 25/065; H01L 25/18; H10B 80/00

(52) U.S. Cl. CPC H01L 24/94; H01L 24/08; H01L 24/80; H01L 25/0657; H01L 25/18; H01L 25/50; H10B 80/00; H01L 2224/08145; H01L 2224/80895; H01L 2224/80896; H01L 2224/94; H01L 2225/06541; H01L 2924/1431; H01L 2924/1436; H01L 2924/37001

(57) ABSTRACT

Methods, systems, and devices for dicing multi-die memory stacks are described. For example, a manufacturing system may form a stack including a silicon material, a first memory stack, a second memory stack, and a scribe structure between the first memory stack and the second memory stack. The first memory stack includes a first memory die coupled with a second memory die and the second memory stack includes a third memory die coupled with a fourth memory die. As such, the manufacturing system may perform a dicing procedure to dice, or separate, the first memory stack and the second memory stack from the scribe structure. Accordingly, the manufacturing system may bond the first memory die of the first memory stack with a first logic die and the third memory die of the second memory stack with a second logic die based on the dicing procedure.

### CROSS REFERENCE

The present Application for Patent claims priority to U.S. Patent Application No. 63/651,879 by Bhushan et al., entitled “DICING MULTI-DIE MEMORY STACKS,” filed May 24, 2024, which is assigned to the assignee hereof, and which is expressly incorporated by reference in its entirety herein.

### TECHNICAL FIELD

The following relates to one or more semiconductor systems, including dicing multi-die memory stacks.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. In some examples, to form memory devices including multiple memory dies, each memory die may be diced (e.g., separated) from respective wafers and subsequently bonded together to form the memory device. However, such techniques may lead to voids between the bonds of each memory die.

### BRIEF DESCRIPTION OF THE DRAWINGS

FIG. 1 shows an example of a system that supports dicing multi-die memory stacks in accordance with examples as disclosed herein.

FIG. 2 shows an example of a memory device that supports dicing multi-die memory stacks in accordance with examples as disclosed herein.

FIG. 3A shows an example of a processing step that supports dicing multi-die memory stacks in accordance with examples as disclosed herein.

FIG. 3B shows an example of a processing step that supports dicing multi-die memory stacks in accordance with examples as disclosed herein.

FIG. 3C shows an example of a processing step that supports dicing multi-die memory stacks in accordance with examples as disclosed herein.

FIG. 3D shows an example of a processing step that supports dicing multi-die memory stacks in accordance with examples as disclosed herein.

FIG. 3E shows an example of a processing step that supports dicing multi-die memory stacks in accordance with examples as disclosed herein.

FIG. 3F shows an example of a processing step that supports dicing multi-die memory stacks in accordance with examples as disclosed herein.

FIG. 3G shows an example of a processing step that supports dicing multi-die memory stacks in accordance with examples as disclosed herein.

FIG. 3H shows an example of a processing step that supports dicing multi-die memory stacks in accordance with examples as disclosed herein.

FIG. 4A shows an example of a processing step that supports dicing multi-die memory stacks in accordance with examples as disclosed herein.

FIG. 4B shows an example of a processing step that supports dicing multi-die memory stacks in accordance with examples as disclosed herein.

FIG. 4C shows an example of a processing step that supports dicing multi-die memory stacks in accordance with examples as disclosed herein.

FIG. 4D shows an example of a processing step that supports dicing multi-die memory stacks in accordance with examples as disclosed herein.

FIG. 4E shows an example of a processing step that supports dicing multi-die memory stacks in accordance with examples as disclosed herein.

FIG. 4F shows an example of a processing step that supports dicing multi-die memory stacks in accordance with examples as disclosed herein.

FIG. 4G shows an example of a processing step that supports dicing multi-die memory stacks in accordance with examples as disclosed herein.

FIGS. 5 and 6 show flowcharts illustrating a method or methods that support dicing multi-die memory stacks in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a DRAM system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some cases, to form the stack of semiconductor components that includes a logic die, a first memory die, and a second memory die, the first memory die and the second memory die may be diced from respective wafers, such that the first memory die may be bonded with the logic die and subsequently the second memory die bonded with the first memory die, thereby forming the stack of semiconductor components. For example, a first wafer may be formed that includes multiple first memory dies. Accordingly, a single stack (e.g., single die) dicing procedure may be performed to dice (e.g., separate) each first memory die on the first wafer, such that each first memory die may be picked up and coupled with a respective logic die. Similarly, a second wafer may be formed that includes multiple second memory dies, where the single stack dicing procedure may be performed to dice each second memory die on the wafer. Accordingly, each second memory die may be picked up and bonded with each first memory die, thereby forming multiple stacks of semiconductor components.

In such cases, however, the single stack (e.g., single die) dicing procedure may introduce silicon particles and various residues (e.g., de-tape residues) on a top surface of each of the memory dies, which may result in bonding voids in the bond between the first memory die and the logic die, voids in the bond between the second memory die and the first memory die, or both. Further, an amount of such residues and silicon particles that are deposited on the top of the memory dies may be further increased when dicing a stack that includes two memory dies (e.g., the first wafer and the second wafer are bonded together prior to the dicing), leading to increased bonding voids. Such voids may decrease the yield of the stack of semiconductor components (e.g., the quantity of functional stacks of semiconductor components). Thus, techniques may be desired to decrease the amount of residue and particles deposited, thereby reducing voids in the bonds and increasing the yield.

According to the techniques described herein, a dicing procedure may be performed to dice memory stacks that include two dies (e.g., dice wafer to wafer stacks) and reduce the amount of silicon particles deposited a top surface of the memory stack. For example, a stack may be formed that includes a first memory stack, a second memory stack, and a scribe structure positioned between the first memory stack and the second memory stack. In such examples, the first memory stack may include a first memory die coupled with a second memory die, while the second memory stack may include a third memory die coupled with a further memory die. Additionally, the stack may include a silicon material deposited under the first memory stack, the second memory stack, and the scribe structure and include a core silicon material positioned between the first and second memory dies, third and further memory dies, and through the scribe structure. In such examples, the stack may be formed by bonding a first wafer that includes at least the first and third memory dies, with a second wafer that at least includes the second and fourth memory dies.

Based on forming the stack, a dicing procedure may be formed to etch a first cavity into a first portion of the scribe structure and to etch a second cavity into a second portion of the scribe structure, where the first cavity and the second cavity extend through a first dielectric material of the scribe structure, through the core silicon material, through a second dielectric material of the scribe structure, and into the silicon material. For example, a first dielectric dry etching procedure may be performed to etch through the first dielectric material of the scribe structure. In response to the first dielectric dry etch, a first plasma etching procedure (e.g., may be performed to etch through the core silicon material of the scribe structure and a second dielectric dry etching procedure may be performed to etch through the second dielectric material of the scribe structure. Based on performing the second dielectric dry etching procedure, a second plasma dry etching procedure may be performed to etch into the silicon material. Accordingly, by performing such an incremental etching procedure, the deposit of silicon particles on the surface of the memory stacks may be mitigated, which may lead to a reduction of bond voids, thereby increasing yield during manufacturing.

In addition to applicability in memory systems as described herein, techniques for dicing multi-die memory stacks may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by reducing voids and gaps in the bond between the memory stacks and the logic dies, which may reduce electronic waste, among other benefits.

Features of the disclosure are illustrated and described in the context of systems and architectures. Features of the disclosure are further illustrated and described in the context of processing steps and flowcharts.

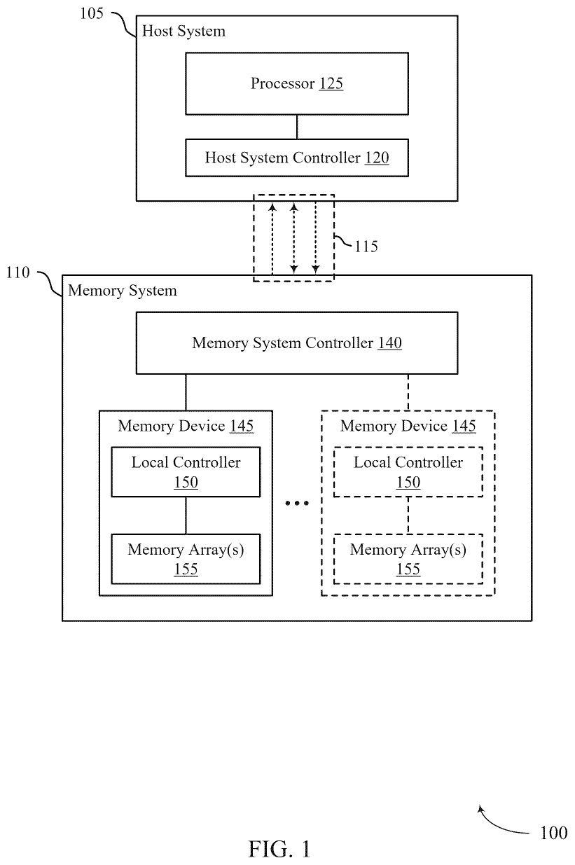

FIG. 1 shows an example of a system 100 that supports dicing multi-die memory stacks in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some cases, to form a memory device 145 that includes a logic die (e.g., logic circuitry or local controller 150), a first memory die, and a second memory die, the first memory die and the second memory die may be diced from respective wafers, such that the first memory die may be bonded with the logic die and subsequently the second memory die bonded with the first memory die, thereby forming the stack of semiconductor components. For example, a first wafer may be formed that includes multiple first memory dies. Accordingly, a single stack (e.g., single die) dicing procedure may be performed to dice (e.g., separate) each first memory die on the first wafer, such that each first memory die may be picked up and coupled with a respective logic die. Similarly, a second wafer may be formed that includes multiple second memory dies, where the single stack dicing procedure may be performed to dice each second memory die on the wafer. Accordingly, each second memory die may be picked up and bonded with each first memory die, thereby forming multiple stacks of semiconductor components.

In such cases, however, the single stack (e.g., single die) dicing procedure may introduce silicon particles and various residues (e.g., de-tape residues) on a top surface of each of the memory dies, which may result in bonding voids in the bond between the first memory die and the logic die, voids in the bond between the second memory die and the first memory die, or both. Further, an amount of such residues and silicon particles that are deposited on the top of the memory dies may be further increased when dicing a stack that includes two memory dies (e.g., the first wafer and the second wafer are bonded together prior to the dicing), leading to increased bonding voids. Such voids may decrease the yield of the stack of semiconductor components (e.g., the quantity of functional stacks of semiconductor components). Thus, techniques may be desired to decrease the amount of residue and particles deposited, thereby reducing voids in the bonds and increasing the yield.

According to the techniques described herein, a dicing procedure may be performed to dice memory stacks that include two dies (e.g., dice wafer-to-wafer stacks) and reduce the amount of silicon particles deposited a top surface of the memory stack. For example, a stack may be formed that includes a first memory stack, a second memory stack, and a scribe structure positioned between the first memory stack and the second memory stack. In such examples, the first memory stack may include a first memory die coupled with a second memory die, while the second memory stack may include a third memory die coupled with a further memory die. Additionally, the stack may include a silicon material deposited under the first memory stack, the second memory stack, and the scribe structure and include a core silicon material positioned between the first and second memory dies, third and further memory dies, and through the scribe structure. In such examples, the stack may be formed by bonding a first wafer that includes at least the first and third memory dies, with a second wafer that at least includes the second and fourth memory dies.

Based on forming the stack, a dicing procedure may be formed to etch a first cavity into a first portion of the scribe structure and to etch a second cavity into a second portion of the scribe structure, where the first cavity and the second cavity extend through a first dielectric material of the scribe structure, through the core silicon material, through a second dielectric material of the scribe structure, and into the silicon material. For example, a first dielectric dry etching procedure may be performed to etch through the first dielectric material of the scribe structure. In response to the first dielectric dry etch, a first plasma etching procedure (e.g., may be performed to etch through the core silicon material of the scribe structure and a second dielectric dry etching procedure may be performed to etch through the second dielectric material of the scribe structure. Based on performing the second dielectric dry etching procedure, a second plasma dry etching procedure may be performed to etch into the silicon material. Accordingly, by performing such an incremental etching procedure, the deposit of silicon particles on the surface of the memory stacks may be mitigated, which may lead to a reduction of bond voids, thereby increasing yield during manufacturing.

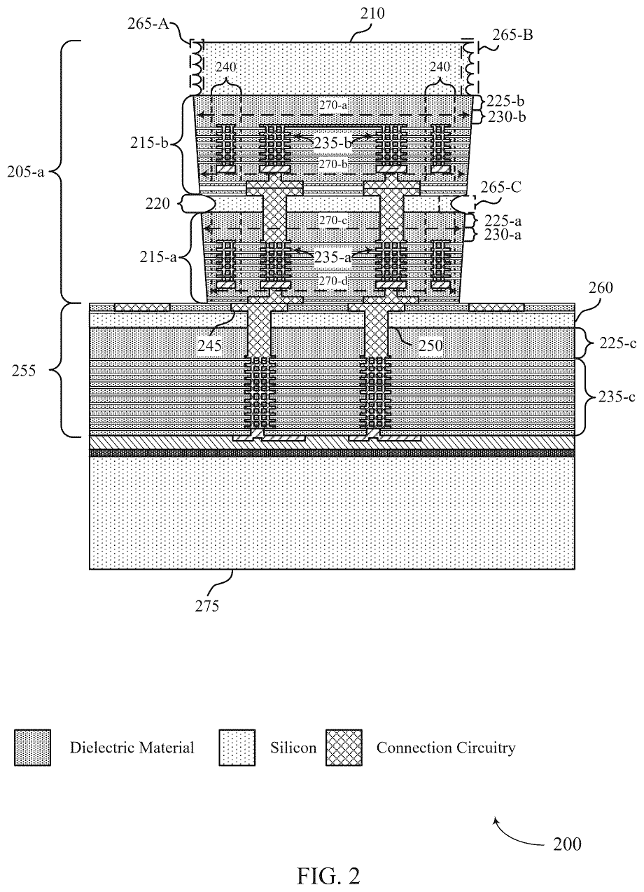

FIG. 2 shows an example of a memory device 200 that supports dicing multi-die memory stacks in accordance with examples as disclosed herein. The memory device 200 may implement, or be implemented by, aspects of the system 100. For example, the memory device 200 may be an example of a memory device 145 as described herein with reference to FIG. 1.

The memory device 200 may include a memory stack 205-a, where the memory stack 205-a may include a silicon material 210 (e.g., a top DRAM silicon), a memory die 215-b, a memory die 215-a, and a core silicon material 220 between the memory die 215-b and the memory die 215-a. In some examples, a memory die 215 may include a dielectric material. A memory die may include one or more layers, such as a layer of transistors 225 (e.g., CMOS transistors) and a layer of memory cells 230. In some examples, the layer of transistors 225 may be on the silicon material 210 (e.g., silicon substrate). Additionally, each memory die 215 may include back end of line (BEOL) circuitry 235 and respective portions of GWOT circuitry 240, where the BEOL circuitry 235 may be coupled with, or be a part of, connection circuitry, such as bond pads 245 and through silicon vias (TSVs) 250.

For example, the memory die 215-b may include a layer of transistors 225-b, a layer of memory cells 230-b, and BEOL circuitry 235-b. In such examples, a first portion of the BEOL circuitry 235-b (e.g., the left BEOL circuitry 235-a of the memory die 215-b) may be coupled with a first TSV 250 and a first bond pad 245 of the memory die 215-b and a second portion of the BEOL circuitry 235-b (e.g., the right BEOL circuitry 235-a of the memory die 215-b) may be coupled with a second TSV 250 and a second bond pad 245 of the memory die 215-b.

Similarly, the memory die 215-a may include a layer of transistors 225-a, a layer of memory cells 230-a, and BEOL circuitry 235-a. In such examples a first portion of the BEOL circuitry 235-a may be coupled with a third TSV 250 and a third bond pad 245 of the memory die 215-a and a second portion of the BEOL circuitry 235-a may be coupled with a fourth TSV 250 and a fourth bond pad 245 of the memory die 215-a. Additionally, the first portion of the BEOL circuitry 235-a may be coupled with a fifth TSV 250 and a fifth bond pad 245 and the second portion of the BEOL circuitry 235-a may be coupled with a sixth TSV 250 and a sixth bond pad 245.

As such, the memory die 215-b may be coupled with (e.g., bonded with) the memory die 215-a, thereby forming the memory stack 205-a. For example, the first bond pad 245 of the memory die 215-b may be coupled with the third bond pad 245 of the memory die 215-a, while the second bond pad 245 of the memory die 215-b may be bonded with the fourth bond pad 245 of the memory die 215-a.

The memory device 200 may also include a logic die 255, where the logic die 255 may include a logical silicon material 260, a layer of transistors 225-c, and BEOL circuitry 235-c. The BEOL circuitry 235-c may be coupled with, or be a part of, the connection circuitry. For example, a first portion of the BEOL circuitry 235-c (e.g., the left portion of the BEOL circuitry 235-c) may be coupled with a seventh TSV 250 and a seventh bond pad 245 of the logic die 255, while a second portion of the BEOL circuitry 235-c (e.g., the right portion of the BEOL circuitry 235-c) may be coupled with an eight TSV 250 and an eight bond pad 245 of the logic die 255. In some examples, the logic die 255 may be bonded with a sacrificial carrier silicon material 275.

In such examples, the memory die 215-a may be coupled with the logic die 255, thereby coupling the memory stack 205-a with the logic die 255. For example, the fifth bond pad 245 of the memory die 215-a may be coupled with the seventh bond pad 245 of the logic die 255, while the sixth bond pad 245 of the memory die 215-a may be coupled with the eighth bond pad 245 of the logic die 255. In this way, the logic die 255 may each memory die 215 via the connection circuitry and BEOL circuitry 235.

In some examples, prior to the memory stack 205-a being coupled with logic die 255, the memory die 215-b and the memory die 215-a may be bonded according to a wafer-to-wafer bond procedure (e.g., wafer-to-wafer hybrid bond). For example, a first wafer may be formed to include multiple memory dies 215, including the memory die 215-a, while a second wafer may be formed to include multiple memory dies 215, including the memory die 215-b. As such, the first wafer may be bonded with the second wafer, thereby forming multiple memory stacks 205, one of which being the memory stack 205-a. In response to bonding the first wafer and the second wafer, the memory stack 205-a may be diced (e.g., etched or separated) from other memory stacks 205 according to an etching procedure.

Based on the memory stack 205-a being separated from the other memory stacks 205, the memory stack 205-a may be bonded with the logic die 255 according to a stack-to-wafer (e.g., device-to-wafer or chip-to-wafer) bonding procedure. For example, a third wafer may be formed that includes multiple logic dies 255, including the logic die 255 illustrated in FIG. 2. Accordingly, in response to the memory stack 205-a being diced, the memory stack 205-a may be bonded with the logic die 255 of the third wafer according to the stack-to-wafer bonding procedure.

In some other examples, the memory stack 205-a may be bonded with the logic die 255 according to a device-to-device bonding procedure. For example, in response to forming the third wafer including the multiple logic dies 255, each logic die 255 included in the third wafer may be diced (e.g., separated) into individual logic dies 255 (e.g., not connected by the same wafer). Accordingly, in response to the memory stack 205-a and the logic die 255 being diced, respectively, the memory stack 205-a may be bonded with the logic die 255 according to the device-to-device bonding procedure.

In some examples, however, during the dicing of the memory stack 205-a, silicon particles and various residues (e.g., de-tape residues) may be deposited on the fifth bond pad 245 and the sixth bond pad 245 (e.g., bonding surface) of the memory die 215-a. Accordingly, when the memory stack 205-a is bonded with the logic die 255, voids in the bond may form due to the deposited silicon particles and various residues on the bonding surface, which may lead to failures when operating the memory device 200.

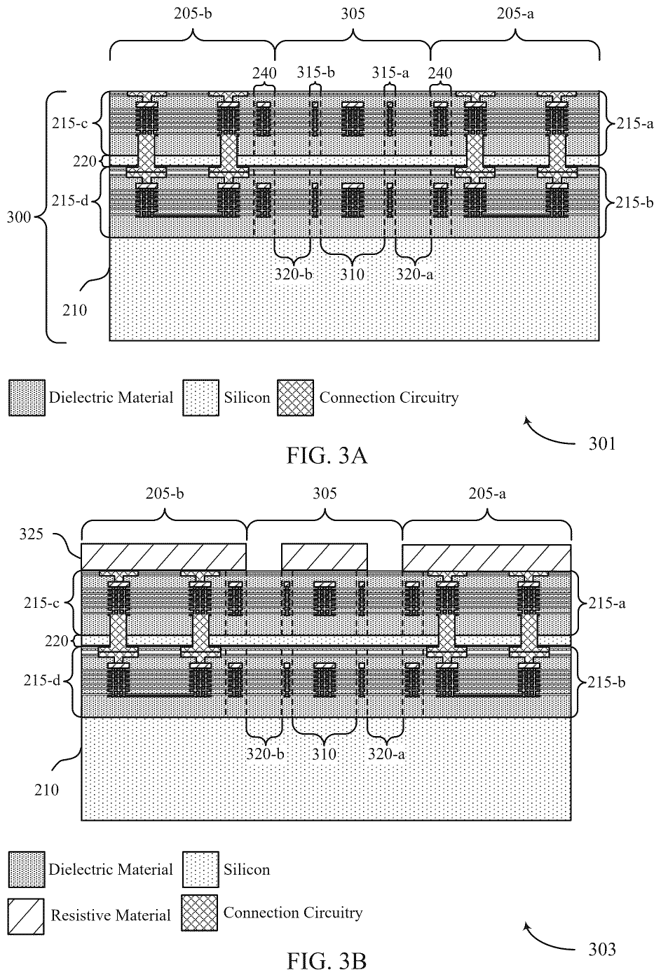

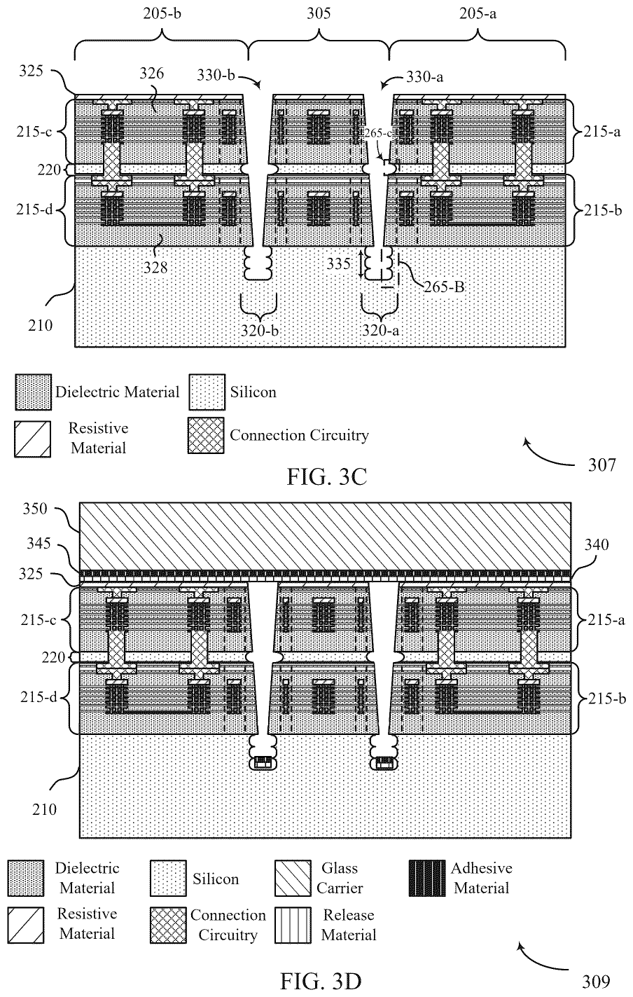

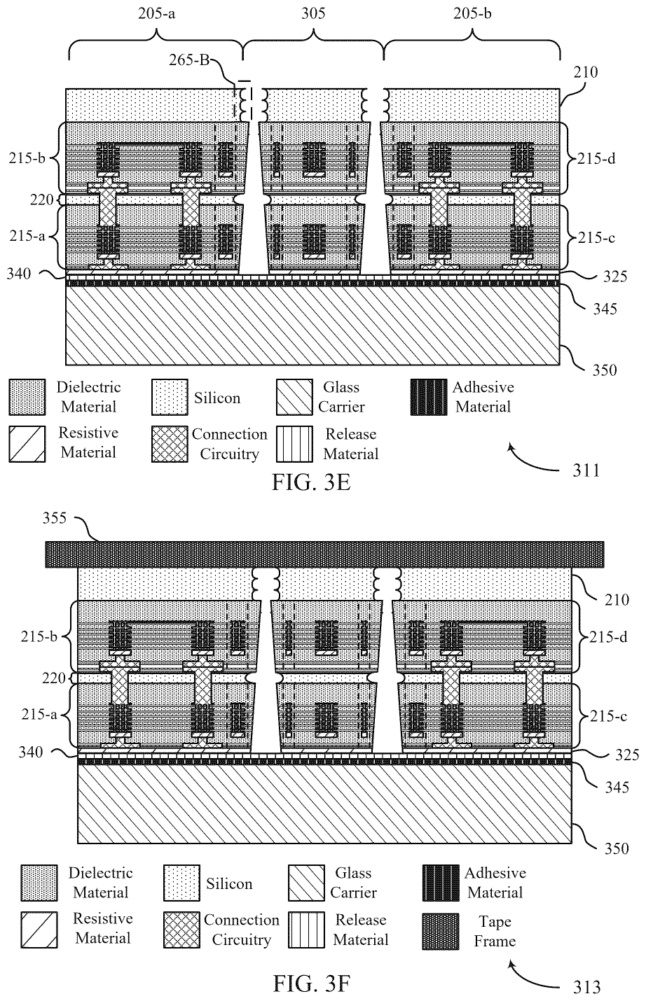

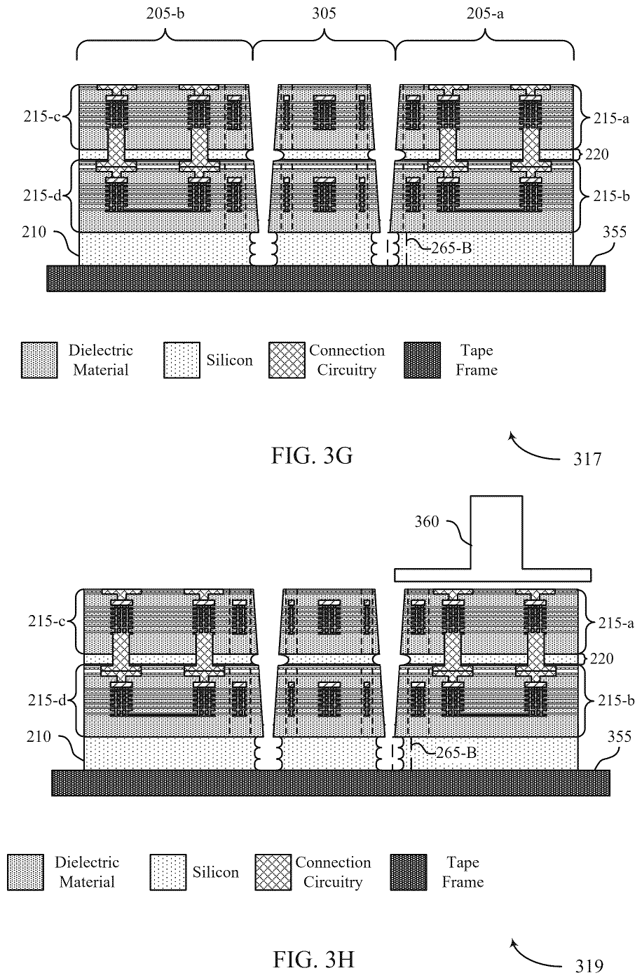

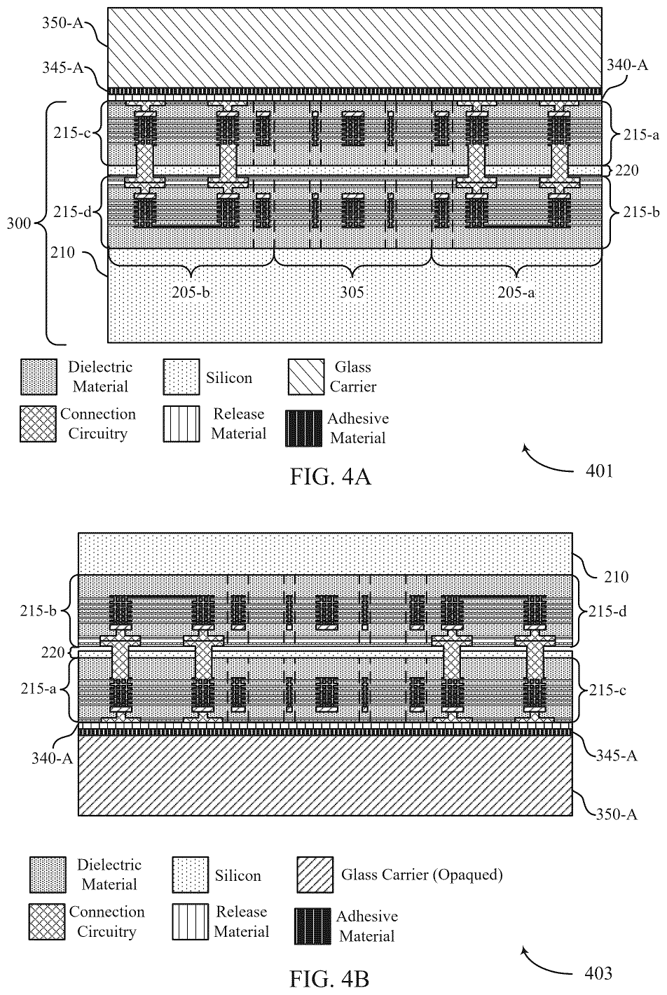

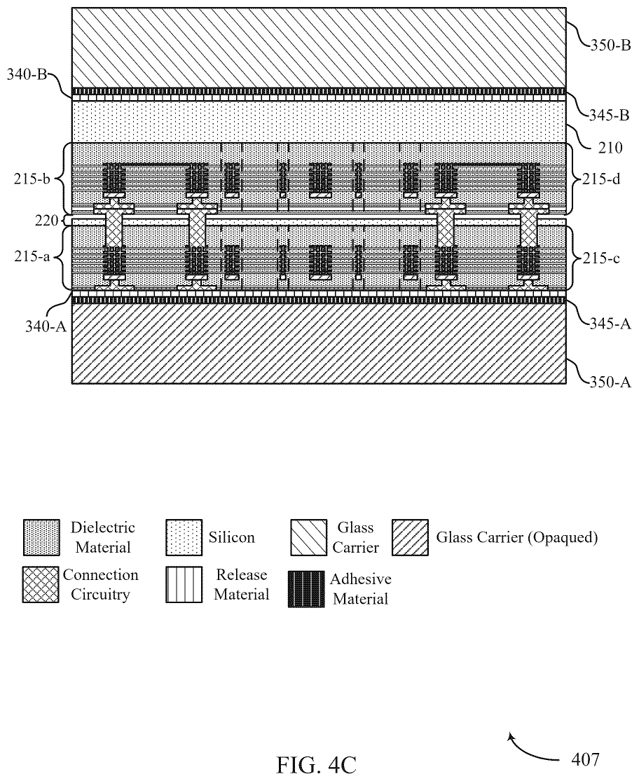

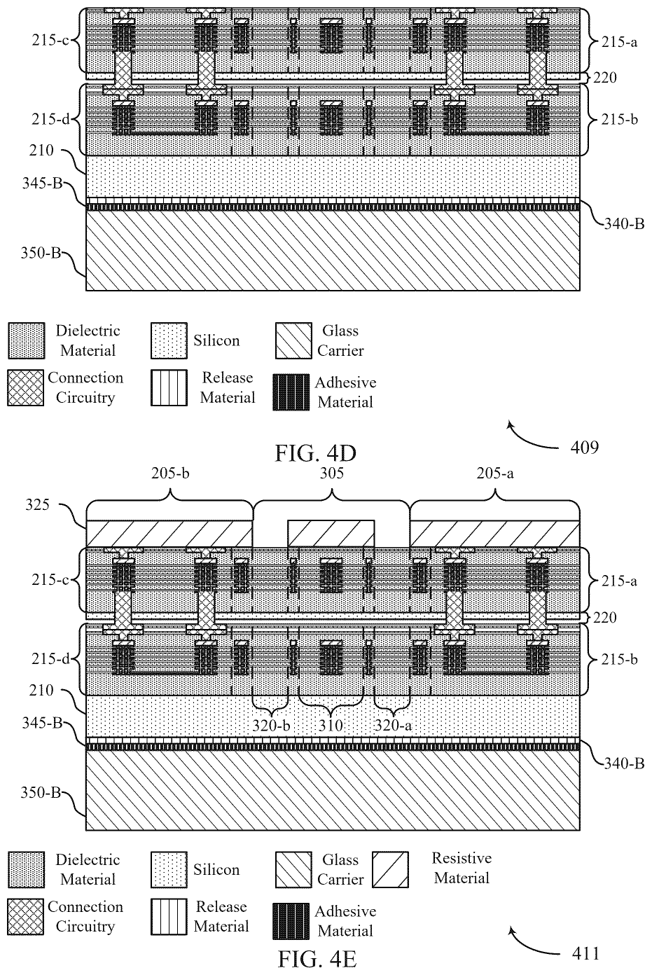

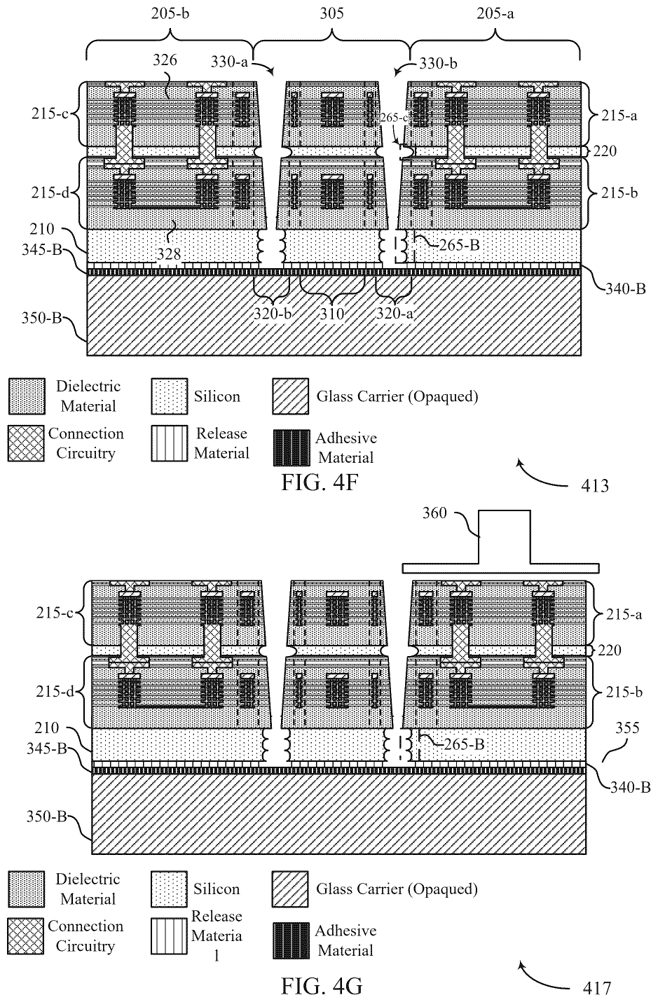

The techniques described herein may provide for a dicing procedure that reduces, or eliminates, the deposit of silicon particles and various residues during the dicing of the memory stack 205-a. The dicing procedure may be further described herein with reference to FIGS. 3C and 4F. In one example, the dicing procedure may be implemented within a first manufacturing process (e.g., stack pick up from tape (STP) process), which may be further described herein with reference to FIGS. 3A-3H. In another example, the dicing procedure may be implemented within a second manufacturing process (e.g., stack pick up from glass (SPG) process), which may be further described hearing with reference to FIGS. 4A-4G.

Due to one or more steps of the dicing procedure, various edges of the silicon material of the memory stack 205-a may develop scallops 265. For example, due to a first plasma dicing procedure and a second plasma dicing procedure (e.g., Bosch dry etch plasma dicing processes), the various edges of the silicon material of the memory stack 205-a may devel the scallops 265. As described herein, a scallop, or scallop pattern, may be an edge of a material having a one or more curves or curve like structures. That is, an edge of the material may have one or more portions of material removed, where such portions may have a circular or curvature like shape. Such curved or circular portions removed from an edge of a material may be referred to as scallops. For example, a first edge of the silicon material 210 may develop scallops 265-a, while a second edge of the silicon material 210 may develop scallops 265-b. Similarly, a first edge of the core silicon material 220 may develop scallops 265 (not shown), and a second edge of the core silicon material 220 may develop scallops 265-c. Additionally, due to the one or more steps of the dicing procedure, the memory stack 205-a may develop a tapered profile. For example, due to a first dielectric dry etching procedure and a second dielectric dry etch procedure (e.g., a core BEOL etch, cell etch, and CMOS transistor dielectric dry etch), the memory stack 205-a may develop a tapered profile. In such examples, a width 270-a of a first portion of the memory die 215-b closest to the silicon material 210 may be greater than a width 270-b of a second portion of the memory die 215-b that is closest to the core silicon material 220. Similarly, a width 270-c of a first portion of the memory die 215-a closest to the core silicon material 220 may be greater than a width 270-d of a second portion of the memory die 215-a that is closest to the logic die 255. Accordingly, the memory stack 205-a may be tapered such that the width 270-a is greater than the width 270-b, the width 270-b is greater than the width 270-c, and the width 270-c is greater than the width 270-d.

In some examples, multiple memory stacks 205 may be connected to the logic die 255 (e.g., single logic die), where each of the multiple memory stacks 205 may be diced according to the techniques described herein. In one illustrative example, the logic die 255 may be coupled with a first memory stack 205, a second memory stack 205, a third memory stack 205, and a fourth memory stack 205, where each of the four memory stacks may be diced according to the techniques described herein with reference to FIG. 3A through 3H or according to the techniques described herein with reference to FIGS. 4A through 4G. In some examples, the logic die 255 may be coupled with multiple unsingulated (e.g., undiced) memory stacks 205, such as coupled with four unsingulated memory stacks 205. In some examples, the orientation of the memory device 200 may be reversed, such that the logic die 255 sits on top of the memory stack 205-a.

FIG. 3A shows an example of a processing step 301 that supports dicing multi-die memory stacks in accordance with examples as disclosed herein. Aspects of the processing step 301 may be implemented in the manufacturing of the memory device 200 using the first manufacturing process (e.g., the SPT process) or the second manufacturing process (SPG process). The processing step 301 may describe the forming of a stack 300.

For example, the stack 300 may be formed, where the stack may include the memory stack 205-a, a memory stack 205-b, and a scribe structure 305 positioned between the memory stack 205-a and the memory stack 205-b, where the memory stack 205-a, the memory stack 205-b, and the scribe structure may be deposited over the silicon material 210. The memory stack 205-a may include the memory die 215-a coupled with the memory die 215-b, while the memory stack 205-b may include a memory die 215-c coupled with a memory die 215-d.

The scribe structure 305 may include a scribe portion 310 (e.g., scribe structure) with a crack stop 315-a between the scribe portion 310 and the memory stack 205-a and a crack stop 315-b between the scribe portion 310 and the memory stack 205-b. Further, the scribe structure 305 may include a metal free lane 320-a between the crack stop 315-a and the memory stack 205-a and a metal free lane 320-b between the crack stop 315-b and the memory stack 205-b.

In such examples, the memory stack 205-a, the memory stack 205-b, and the scribe structure 305 may be formed according to a wafer-to-wafer bonding procedure (e.g., wafer-to-wafer hybrid bonding procedure). For example, a first wafer may be formed that at least includes the memory die 215-c, the memory die 215-a, and a first portion of the scribe structure 305, while a second wafer may be formed that at least includes the memory die 215-d, the memory die 215-b, and a second portion of the scribe structure 305. Accordingly, the first wafer may be bonded with (e.g., coupled with) the second wafer, such that the memory stack 205-a, the scribe structure 305, and the memory stack 205-b are formed.

FIG. 3B shows an example of a processing step 303 that supports dicing multi-die memory stacks in accordance with examples as disclosed herein. Aspects of the processing step 303 may be implemented in the manufacturing of the memory device 200 using the first manufacturing process (e.g., the SPT process) and occur subsequent to the processing step 301. The techniques described in the processing step 303 may provide for photo resistive material patterning.

For example, in response to forming the stack 300 as described in the processing step 301, a resistive material 325 (e.g., photo resistive material) may be deposited over the memory stack 205-b, the scribe structure 305, and the memory stack 205-a. In response to depositing the resistive material 325, portions of the resistive material 325 that are over the metal free lane 320-a (e.g., first portion) of the scribe structure 305 and the metal free lane 320-b (e.g., second portion) of the scribe structure 305 may be removed.

Alternatively, in some examples, a first portion of the resistive material 325 may be deposited over the memory stack 205-a, while a second portion of the resistive material 325 may be deposited over the scribe portion 310 and crack stops 315 of the scribe structure 305, and a third portion of the resistive material 325 may be deposited over the memory stack 205-b. In this way, the removal of portions of the resistive material may be avoided.

FIG. 3C shows an example of a processing step 307 that supports dicing multi-die memory stacks in accordance with examples as disclosed herein. Aspects of the processing step 307 may be implemented in the manufacturing of the memory device 200 using the first manufacturing process (e.g., the SPT process) and occur subsequent to the processing step 303. The processing step 307 may describe dicing the memory stacks 205 according to the dicing procedure.

For example, the dicing procedure may be performed to etch a cavity 330-a (e.g., first cavity) through the metal free lane 320-a and etch a cavity 330-b (e.g., a second cavity) through the metal free lane 320-b, thereby dicing (e.g., separating) the memory stack 205-a and the memory stack 205-b from the scribe structure 305. That is, the cavity 330-a may be etched through a dielectric material 326 of the metal free lane 320-a (e.g., the first dielectric material), through the core silicon material 220 of the metal free lane 320-a, through a dielectric material 328 of the metal free lane 320-a (e.g., second dielectric material), and into a portion 335 (e.g., first portion) of the silicon material 210. Similarly, the cavity 330-b may be etched through the dielectric material 326 of the metal free lane 320-b, through the core silicon material 220 of the metal free lane 320-b, through the dielectric material 328 of the metal free lane 320-b, and into the silicon material 210. In such examples, the dicing procedure may be performed from the front side of the die 215-a to the backside of the die 215-b (e.g., from the top down). Similarly, the dicing procedure may be performed from the front side of the die 215-b to the backside of the die 215-b (e.g., from the top down). Likewise, the dicing procedure may be performed from the front side of the die 215-c to the backside of the die 215-c (e.g., from the top down). Similarly, the dicing procedure may be performed from the front side of the die 215-d to the backside of the die 215-d (e.g., from the top down).

In such examples, the dicing procedure may involve one or more etching procedures. For example, a first dielectric dry etch procedure (e.g., a core BEOL etch, cell etch, and CMOS transistor dielectric dry etch) may be performed to etch through the dielectric material 326 of the metal free lanes 320. That is, the first dielectric etch procedure may etch through the BEOL layer, etch through the layer of cells 230-b, and etch through the layer of transistors 235 of the metal free lanes 320 corresponding to the dies 215-a and 215-c. Following the first dielectric dry etch procedure, a first plasma etching procedure (e.g., silicon plasma etching procedure or Bosch silicon dry etching procedure) may be performed to etch through the core silicon material 220. In response to the first plasma etching procedure, a second dielectric dry etch procedure (e.g., a core BEOL etch, cell etch, and CMOS transistor dielectric dry etch) may be performed to etch through the dielectric material 328 of the metal free lanes 320. That is, the first dielectric etch procedure may etch through the BEOL layer, etch through the layer of cells 230-b, and etch through the layer of transistors 235 of the metal free lanes 320 corresponding to the dies 215-b and 215-d. Following the second dielectric dry etch procedure, a second plasma etching procedure (e.g., silicon plasma dicing) may be performed to etch into the portion 335 of the silicon material 210.

In such examples, due to the first and second dielectric dry etch procedures, the etched sides of the memory stack 205-a and the memory stack 205-b may develop a tapered profile, as described herein with reference to FIG. 2. Additionally, due to the first and second plasma etching procedures, the core silicon material 220 and the silicon material 210 may develop scallops 265, as described herein with reference to FIG. 2. By performing the one or more steps of the dicing procedure, the deposit of silicon particles during the dicing of the memory stacks 205 may be mitigated. For example, by applying the resistive material 325, the bonding surfaces of the memory die 215-a and the memory die 215-c may be protected, thereby reducing the silicon particles that may be deposited. Additionally, the performance of the first and second plasma etching procedures may reduce the amount of silicon particles reduced, thereby mitigating the amount of silicon particles.

In some examples, in response to etching the cavity 330-a and the cavity 330-b, the resistive material 325 may be thinned, such that de-bond residues in subsequent processing steps may be mitigated. Alternatively, in response to etching the cavity 330-a and the cavity 330-b, the resistive material 325 may be removed.

FIG. 3D shows an example of a processing step 309 that supports dicing multi-die memory stacks in accordance with examples as disclosed herein. Aspects of the processing step 309 may be implemented in the manufacturing of the memory device 200 using the first manufacturing process (e.g., the SPT process) and occur subsequent to the processing step 307. The processing step 309 may describe bonding, temporarily, the stack 300 with a glass carrier 350.

For example, in response to dicing the memory stacks 205, a release material 340 may be deposited over the memory stack 205-a, the memory stack 205-b, and the scribe structure. In such examples, a portion of the release material 340 may be deposited into the cavities 330. The release material 340 may be a material that provides for a reduced amount of residue during the removal of the release material 340 from stack 300. In response to depositing the release material 340, an adhesive material 345 may be deposited over the release material. Similarly, a portion of the adhesive material 345 may be deposited into the cavities 330. Based on depositing the adhesive material 345, the adhesive material may be bonded with the glass carrier 350.

FIG. 3E shows an example of a processing step 311 that supports dicing multi-die memory stacks in accordance with examples as disclosed herein. Aspects of the processing step 311 may be implemented in the manufacturing of the memory device 200 using the first manufacturing process (e.g., the SPT process) and occur subsequent to the processing step 309. The processing step 311 may describe thinning the silicon material 210 according to one or more procedures.

For example, in response to bonding the stack 300 with the glass carrier 350, the stack 300 may be rotated 180 degrees, such that the stack 300 sits on the glass carrier 350. In response to rotating the stack 300, the silicon material 210 may be thinned by removing a portion of the silicon material 210. In such examples, the portion of the silicon material 210 that is removed may be based on a length of the portion 335, such that each memory stack 205 may be fully separated.

In some examples, to thin the portion of the silicon material 210, a chemical-mechanical polishing (CMP) procedure may be performed, a dry etching procedure may be performed, a cleaning procedure (CLN) procedure may be performed, a laser etching procedure (e.g., BG etching) may be performed, or a combination of such procedures may be performed.

FIG. 3F shows an example of a processing step 313 that supports dicing multi-die memory stacks in accordance with examples as disclosed herein. Aspects of the processing step 313 may be implemented in the manufacturing of the memory device 200 using the first manufacturing process (e.g., the SPT process) and occur subsequent to the processing step 311. The processing step 313 may describe mounting a tape frame 355. For example, the tape frame 355 may be a tool used to hold and protect the memory stacks 205 during packaging or bonding of the memory stacks 205 with a respective logic die 255. Accordingly, in response to thinning the silicon material 210, such that each memory stack 205 is fully diced, the tape frame 355 may be bonded with the silicon material 210.

FIG. 3G shows an example of a processing step 317 that supports dicing multi-die memory stacks in accordance with examples as disclosed herein. Aspects of the processing step 317 may be implemented in the manufacturing of the memory device 200 using the first manufacturing process (e.g., the SPT process) and occur subsequent to the processing step 313. The processing step 317 may describe the removal of the glass carrier 350, the adhesive material 345, the release material 340, the resistive material 325, or a combination thereof.

For example, in response to mounting the tape frame to the stack 300, the stack 300 may be rotated by 180 degrees to sit on the tape frame 355. In response to rotating the stack 300, the glass carrier 350 may be de-bonded from the adhesive material 345 according to a laser de-debonding procedure. Based on removing the glass carrier 350, the adhesive material 345 and the release material 340 may be removed. In such examples, the adhesive material 345 and the release material 340 may be removed according to a CLN procedure. Additionally, if the resistive material 325 was thinned and maintained at the processing step 307, then the resistive material 325 may be removed according to a CLN procedure.

FIG. 3H shows an example of a processing step 319 that supports dicing multi-die memory stacks in accordance with examples as disclosed herein. Aspects of the processing step 319 may be implemented in the manufacturing of the memory device 200 using the first manufacturing process (e.g., the SPT process) and occur subsequent to the processing step 317. The processing step 319 may describe the pickup of each memory stack 205 in preparation for bonding with a respective logic die 255. For example, a pickup nozzle 360 may be used to pick up (e.g., retrieve) each memory stack 205 from the tape frame 355 in preparation for bonding with the respective logic die 255. Accordingly, in response to being picked up from the tape frame 355 and rotated, each memory stack 205 may be bonded with the respective logic die 255 according to the techniques described herein with reference to FIG. 2. For example, the memory stack 205-a may be bonded with the logic die 255, thereby forming the memory device 200.

FIG. 4A shows an example of a processing step 401 that supports dicing multi-die memory stacks in accordance with examples as disclosed herein. Aspects of the processing step 401 may be implemented in the manufacturing of the memory device 200 using the second manufacturing process (e.g., the SPG process) and occur subsequent to the processing step 301. The techniques described in the processing step 401 may provide for a temporary bonding between the stack 300 and a glass carrier 350-a (e.g., a second glass carrier).

In response to forming the stack 300, a release material 340-a may be deposited over the memory stack 205-a, the scribe structure 305, and the memory stack 205-b. Based on depositing the release material 340-a, an adhesive material 345-a may be deposited over the release material 340-a. Based on depositing the adhesive material 345-a, the stack 300 may be bonded with the glass carrier 350-a. That is, the adhesive material 345-a may be bonded with the glass carrier 350-a, thereby bonding the stack 300 with the glass carrier 350-a.

FIG. 4B shows an example of a processing step 403 that supports dicing multi-die memory stacks in accordance with examples as disclosed herein. Aspects of the processing step 403 may be implemented in the manufacturing of the memory device 200 using the second manufacturing process (e.g., the SPG process) and occur subsequent to the processing step 401. The processing step 403 may describe thinning the silicon material 210 according to one or more procedures and de-opaquing the glass carrier 350-a.

For example, in response to bonding the stack 300 with the glass carrier 350-a, the stack 300 may be rotated 180 degrees, such that the stack 300 sits on the glass carrier 350-a. In response to rotating the stack 300, the silicon material 210 may be thinned by removing a portion of the silicon material 210. In some examples, to thin the portion of the silicon material 210, a CMP procedure may be performed, a dry etching procedure may be performed, a CLN procedure may be performed, a laser etching procedure (e.g., BG etching) may be performed, or a combination of such procedures may be performed. Additionally, in conjunction with, prior to, or after, thinning the silicon material 210, the glass carrier 350-a may be de-opaqued, such that the glass carrier 350-a may have an increased transparency.

FIG. 4C shows an example of a processing step 407 that supports dicing multi-die memory stacks in accordance with examples as disclosed herein. Aspects of the processing step 407 may be implemented in the manufacturing of the memory device 200 using the second manufacturing process (e.g., the SPG process) and occur subsequent to the processing step 403. The techniques described in the processing step 407 may provide for a temporary bonding between the stack 300 and a glass carrier 350-b (e.g., a first glass carrier).

In response to thinning the silicon material 210, a release material 340-b may be deposited over the silicon material 210. Based on depositing the release material 340-b, an adhesive material 345-b may be deposited over the release material 340-b. Based on depositing the adhesive material 345-b, the stack 300 may be bonded with the glass carrier 350-. That is, the adhesive material 345-b may be bonded with the glass carrier 350-b, thereby bonding the stack 300 with the glass carrier 350-b.

FIG. 4D shows an example of a processing step 409 that supports dicing multi-die memory stacks in accordance with examples as disclosed herein. Aspects of the processing step 409 may be implemented in the manufacturing of the memory device 200 using the second manufacturing process (e.g., the SPG process) and occur subsequent to the processing step 407. The processing step 409 may describe the removal of the glass carrier 350-a, the adhesive material 345-a, and the release material 340-a. For example, in response to bonding the glass carrier 350-b, the stack 300 may be rotated by 180 degrees to sit on the glass carrier 350-b. In response to rotating the stack 300, the glass carrier 350-a may be de-bonded from the adhesive material 345-a according to a laser de-debonding procedure. Based on removing the glass carrier 350-a, the adhesive material 345-a and the release material 340-a may be removed. In such examples, the adhesive material 345-a and the release material 340-a may be removed according to a CLN procedure.

FIG. 4E shows an example of a processing step 411 that supports dicing multi-die memory stacks in accordance with examples as disclosed herein. Aspects of the processing step 411 may be implemented in the manufacturing of the memory device 200 using the second manufacturing process (e.g., the SPG process) and occur subsequent to the processing step 409. The techniques described in the processing step 411 may provide for photo resistive material patterning.

For example, in response to removing the glass carrier 350-a, the adhesive material 345-a, and the release material 340-a, a resistive material 325 (e.g., photo resistive material) may be deposited over the memory stack 205-b, the scribe structure 305, and the memory stack 205-a. In response to depositing the resistive material 325, portions of the resistive material 325 that are over the metal free lane 320-a (e.g., first portion) of the scribe structure 305 and the metal free lane 320-b (e.g., second portion) of the scribe structure 305 may be removed. Alternatively, in some examples, a first portion of the resistive material 325 may be deposited over the memory stack 205-a, while a second portion of the resistive material 325 may be deposited over the scribe portion 310 and crack stops 315 of the scribe structure 305, and a third portion of the resistive material 325 may be deposited over the memory stack 205-b. In this way, the removal of portions of the resistive material may be avoided.

FIG. 4F shows an example of a processing step 413 that supports dicing multi-die memory stacks in accordance with examples as disclosed herein. Aspects of the processing step 413 may be implemented in the manufacturing of the memory device 200 using the second manufacturing process (e.g., the SPG process) and occur subsequent to the processing step 411. The techniques described in the processing step 413 may describe dicing the memory stacks 205 according to the dicing procedure.

For example, the dicing procedure may be performed to etch a cavity 330-a (e.g., first cavity) through the metal free lane 320-a and etch a cavity 330-b (e.g., a second cavity) through the metal free lane 320-b, thereby dicing (e.g., separating) the memory stack 205-a and the memory stack 205-a from the scribe structure 305. That is, the cavity 330-a may be etched through a dielectric material 326 of the metal free lane 320-a (e.g., the first dielectric material), through the core silicon material 220 of the metal free lane 320-a, through a dielectric material 328 of the metal free lane 320-a (e.g., second dielectric material), and into a portion 335 (e.g., first portion) of the silicon material 210. Similarly, the cavity 330-b may be etched through the dielectric material 326 of the metal free lane 320-b, through the core silicon material 220 of the metal free lane 320-b, through the dielectric material 328 of the metal free lane 320-b, and into the silicon material 210.

In such examples, the dicing procedure may involve one or more etching procedures. For example, a first dielectric dry etch procedure may be performed to etch through the dielectric material 326 of the metal free lanes 320. Following the first dielectric dry etch procedure, a first plasma etching procedure (e.g., silicon plasma etching procedure or Bosch silicon dry etching procedure) may be performed to etch through the core silicon material 220. In response to the first plasma etching procedure, a second dielectric dry etch procedure may be performed to etch through the dielectric material 328 of the metal free lanes 320. Following the second dielectric dry etch procedure, a second plasma etching procedure may be performed to etch through the silicon material 210 and into the release material 340-b. Accordingly, by etching through the silicon material 210, each memory stack 205 may be fully diced (e.g., fully separated).

In some examples, in response to etching the cavity 330-a and the cavity 330-b, the resistive material 325 may be removed according to a cleaning procedure. Additionally, in conjunction with, prior to, or after, dicing the memory stacks 205, the glass carrier 350-b may be de-opaqued, such that the glass carrier 350-b may have an increased transparency.

Due to the first and second dielectric dry etch procedures, the etched sides of the memory stack 205-a and the memory stack 205-b may develop a tapered profile, as described herein with reference to FIG. 2. Additionally, due to the first and second plasma etching procedures, the core silicon material 220 and the silicon material 210 may develop scallops 265, as described herein with reference to FIG. 2. By performing the one or more steps of the dicing procedure, the deposit of silicon particles during the dicing of the memory stacks 205 may be mitigated. For example, by applying the resistive material 325, the bonding surfaces of the memory die 215-a and the memory die 215-c may be protected, thereby reducing the silicon particles that may be deposited. Additionally, the performance of the first and second plasma etching procedures may reduce the amount of silicon particles reduced, thereby mitigating the amount of silicon particles.

FIG. 4G shows an example of a processing step 417 that supports dicing multi-die memory stacks in accordance with examples as disclosed herein. Aspects of the processing step 417 may be implemented in the manufacturing of the memory device 200 using the second manufacturing process (e.g., the SPG process) and occur subsequent to the processing step 413. The techniques described in the processing step 417 may describe the pickup of each memory stack 205 in preparation for bonding with a respective logic die 255. For example, a pickup nozzle 360 may be used to pick up (e.g., retrieve) each memory stack 205 from the glass carrier 350-b in preparation for bonding with the respective logic die 255. Accordingly, in response to being picked up from the glass carrier 350-b and rotated, each memory stack 205 may be bonded with the respective logic die 255 according to the techniques described herein with reference to FIG. 2. For example, the memory stack 205-a may be bonded with the logic die 255, thereby forming the memory device 200.

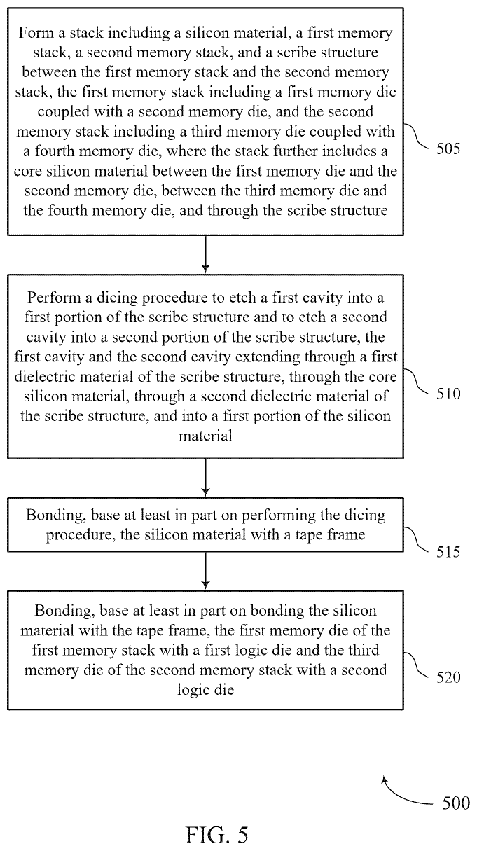

FIG. 5 shows a flowchart illustrating a method 500 that supports dicing multi-die memory stacks in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method 500 may include forming a stack including a silicon material, a first memory stack, a second memory stack, and a scribe structure between the first memory stack and the second memory stack, the first memory stack including a first memory die coupled with a second memory die, and the second memory stack including a third memory die coupled with a fourth memory die, where the stack further includes a core silicon material between the first memory die and the second memory die, between the third memory die and the fourth memory die, and through the scribe structure.

At 510, the method 500 may include performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and into a first portion of the silicon material.

At 515, the method 500 may include bonding, based at least in part on performing the dicing procedure, the silicon material with a tape frame.

At 520, the method 500 may include bonding, based at least in part on bonding the silicon material with the tape frame, the first memory die of the first memory stack with a first logic die and the third memory die of the second memory stack with a second logic die.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a stack including a silicon material, a first memory stack, a second memory stack, and a scribe structure between the first memory stack and the second memory stack, the first memory stack including a first memory die coupled with a second memory die, and the second memory stack including a third memory die coupled with a fourth memory die, where the stack further includes a core silicon material between the first memory die and the second memory die, between the third memory die and the fourth memory die, and through the scribe structure; performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and into a first portion of the silicon material; bonding, based at least in part on performing the dicing procedure, the silicon material with a tape frame; and bonding, based at least in part on bonding the silicon material with the tape frame, the first memory die of the first memory stack with a first logic die and the third memory die of the second memory stack with a second logic die.

Aspect 2: The method or apparatus of aspect 1, where performing the dicing procedure includes operations, features, circuitry, logic, means, or instructions, or any combination thereof for performing a first dielectric dry etching procedure to etch the first dielectric material of the scribe structure; performing a first plasma dry etching procedure to etch the core silicon material of the scribe structure; performing a second dielectric dry etching procedure to etch the second dielectric material of the scribe structure; and performing a second plasma dry etching procedure to etch into the first portion of the silicon material.

Aspect 3: The method or apparatus of any of aspects 1 through 2, further including operations, features, circuitry, logic, means, or instructions, or any combination thereof for depositing a resistive material over the first memory stack, the second memory stack, and the scribe structure, where performing the dicing procedure is based at least in part on depositing the resistive material.

Aspect 4: The method or apparatus of aspect 3, further including operations, features, circuitry, logic, means, or instructions, or any combination thereof for removing portions of the resistive material that are over the first portion of the scribe structure and the second portion of the scribe structure, where performing the dicing procedure into the first portion of the scribe structure and the second portion of the scribe structure is based at least in part on removing the portions of the resistive material.

Aspect 5: The method or apparatus of any of aspects 3 through 4, further including operations, features, circuitry, logic, means, or instructions, or any combination thereof for removing the resistive material from the first memory die, the second memory die, and the scribe structure, where bonding the first memory die to the first logic die and bonding the second memory die to the second logic die is based at least in part on removing the resistive material.

Aspect 6: The method or apparatus of any of aspects 1 through 5, further including operations, features, circuitry, logic, means, or instructions, or any combination thereof for thinning the silicon material by removing a second portion of the silicon material, where the second portion of the silicon material that is removed is based at least in part on a length of the first portion of the silicon material, and where bonding the silicon material with the tape frame is based at least in part on thinning the silicon material.

Aspect 7: The method or apparatus of aspect 6, where the second portion of the silicon material is removed using a CMP procedure, a dry etching procedure, a cleaning procedure, a laser etching procedure, or any combination thereof.

Aspect 8: The method or apparatus of any of aspects 1 through 7, further including operations, features, circuitry, logic, means, or instructions, or any combination thereof for depositing, based at least in part on performing the dicing procedure, a release material over the first memory stack, over the second memory stack, and over the scribe structure; depositing an adhesive material over the release material; and bonding a glass carrier with the adhesive material, where bonding the silicon material with the tape frame is based at least in part on bonding the glass carrier with the adhesive material.

Aspect 9: The method or apparatus of aspect 8, further including operations, features, circuitry, logic, means, or instructions, or any combination thereof for removing the glass carrier, the adhesive material, and the release material based at least in part on bonding the silicon material with the tape frame, where bonding the first memory die with the first logic die and bonding the second memory die with the second logic die is based at least in part on removing the glass carrier, the adhesive material, and the release material.

Aspect 10: The method or apparatus of aspect 9, where removing the glass carrier includes operations, features, circuitry, logic, means, or instructions, or any combination thereof for performing a laser debonding procedure to debond the glass carrier from the adhesive material.

Aspect 11: The method or apparatus of any of aspects 9 through 10, where the adhesive material and the release material are removed using a cleaning procedure based at least in part on removing the glass carrier.

Aspect 12: The method or apparatus of any of aspects 1 through 11, further including operations, features, circuitry, logic, means, or instructions, or any combination thereof for bonding a first wafer of memory dies with a second wafer of memory dies to form the first memory stack and the second memory stack, where forming the stack is based at least in part on bonding the first wafer with the second wafer.

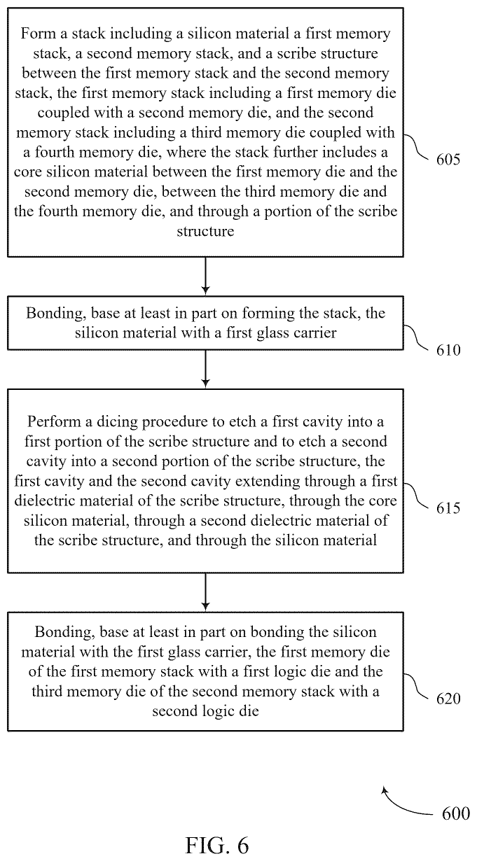

FIG. 6 shows a flowchart illustrating a method 600 that supports dicing multi-die memory stacks in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method 600 may include forming a stack including a silicon material a first memory stack, a second memory stack, and a scribe structure between the first memory stack and the second memory stack, the first memory stack including a first memory die coupled with a second memory die, and the second memory stack including a third memory die coupled with a fourth memory die, where the stack further includes a core silicon material between the first memory die and the second memory die, between the third memory die and the fourth memory die, and through a portion of the scribe structure.

At 610, the method 600 may include bonding, based at least in part on forming the stack, the silicon material with a first glass carrier.

At 615, the method 600 may include performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and through the silicon material.

At 620, the method 600 may include bonding, based at least in part on bonding the silicon material with the first glass carrier, the first memory die of the first memory stack with a first logic die and the third memory die of the second memory stack with a second logic die.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 13: A method or apparatus including operations, features, circuitry, logic, means, or instructions, or any combination thereof for forming a stack including a silicon material a first memory stack, a second memory stack, and a scribe structure between the first memory stack and the second memory stack, the first memory stack including a first memory die coupled with a second memory die, and the second memory stack including a third memory die coupled with a fourth memory die, where the stack further includes a core silicon material between the first memory die and the second memory die, between the third memory die and the fourth memory die, and through a portion of the scribe structure; bonding, based at least in part on forming the stack, the silicon material with a first glass carrier; performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and through the silicon material; and bonding, based at least in part on bonding the silicon material with the first glass carrier, the first memory die of the first memory stack with a first logic die and the third memory die of the second memory stack with a second logic die.

Aspect 14: The method or apparatus of aspect 13, where performing the dicing procedure includes operations, features, circuitry, logic, means, or instructions, or any combination thereof for performing a first dielectric dry etching procedure to etch the first dielectric material of the scribe structure; performing a first plasma dry etching procedure to etch the core silicon material of the scribe structure; performing a second dielectric dry etching procedure to etch the second dielectric material of the scribe structure; and performing a second plasma dry etching procedure to etch through the silicon material.

Aspect 15: The method or apparatus of any of aspects 13 through 14, further including operations, features, circuitry, logic, means, or instructions, or any combination thereof for depositing a release material over the first memory stack, over the second memory stack, and over the scribe structure; depositing an adhesive material over the release material; and bonding a second glass carrier with the adhesive material, where bonding the silicon material with the first glass carrier is based at least in part on bonding the second glass carrier with the adhesive material.

Aspect 16: The method or apparatus of aspect 15, further including operations, features, circuitry, logic, means, or instructions, or any combination thereof for de-opaquing the second glass carrier based at least in part on bonding the second glass carrier with the adhesive material.

Aspect 17: The method or apparatus of any of aspects 15 through 16, further including operations, features, circuitry, logic, means, or instructions, or any combination thereof for removing the second glass carrier, the adhesive material, and second release material based at least in part on bonding the silicon material with the first glass carrier, where performing the dicing procedure is based at least in part on removing the second glass carrier, the adhesive material, and the release material.

Aspect 18: The method or apparatus of aspect 17, where removing the second glass carrier includes operations, features, circuitry, logic, means, or instructions, or any combination thereof for performing a laser debonding procedure to debond the second glass carrier from the adhesive material.

Aspect 19: The method or apparatus of any of aspects 17 through 18, where the adhesive material and the release material are removed using a cleaning procedure based at least in part on removing the second glass carrier.

Aspect 20: The method or apparatus of any of aspects 13 through 19, further including operations, features, circuitry, logic, means, or instructions, or any combination thereof for thinning the silicon material by removing a portion of the silicon material, where bonding the silicon material with the first glass carrier is based at least in part on thinning the silicon material.

Aspect 21: The method or apparatus of aspect 20, where the portion of the silicon material is removed using a chemical-mechanical polishing (CMP) procedure, a dry etching procedure, a cleaning procedure, a laser etching procedure, or any combination thereof.

Aspect 22: The method or apparatus of any of aspects 13 through 21, where bonding the silicon material with the first glass carrier includes operations, features, circuitry, logic, means, or instructions, or any combination thereof for depositing a release material over the silicon material and depositing an adhesive material over the release material, where the first glass carrier is bonded with the adhesive material.

Aspect 23: The method or apparatus of any of aspects 13 through 22, further including operations, features, circuitry, logic, means, or instructions, or any combination thereof for depositing a resistive material over the first memory stack, the second memory stack, and the scribe structure, where performing the dicing procedure is based at least in part on depositing the resistive material.

Aspect 24: The method or apparatus of aspect 23, further including operations, features, circuitry, logic, means, or instructions, or any combination thereof for removing portions of the resistive material that are over the first portion of the scribe structure and the second portion of the scribe structure, where performing the dicing procedure into the first portion of the scribe structure and the second portion of the scribe structure is based at least in part on removing the portions of the resistive material.

Aspect 25: The method or apparatus of any of aspects 23 through 24, further including operations, features, circuitry, logic, means, or instructions, or any combination thereof for removing the resistive material from the first memory die, the second memory die, and the scribe structure, where bonding the first memory die to the first logic die and bonding the second memory die to the second logic die is based at least in part on removing the resistive material.

Aspect 26: The method or apparatus of any of aspects 13 through 25, further including operations, features, circuitry, logic, means, or instructions, or any combination thereof for de-opaquing the first glass carrier based at least in part on performing the dicing procedure.

Aspect 27: The method or apparatus of any of aspects 13 through 26, further including operations, features, circuitry, logic, means, or instructions, or any combination thereof for bonding a first wafer of memory dies with a second wafer of memory dies to form the first memory stack and the second memory stack, where forming the stack is based at least in part on bonding the first wafer with the second wafer.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method for manufacturing a memory device, comprising:
forming a stack comprising a silicon material, a first memory stack, a second memory stack, and a scribe structure between the first memory stack and the second memory stack, the first memory stack comprising a first memory die coupled with a second memory die, and the second memory stack comprising a third memory die coupled with a fourth memory die, wherein the stack further comprises a core silicon material between the first memory die and the second memory die, between the third memory die and the fourth memory die, and through the scribe structure;
performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and into a first portion of the silicon material;
bonding, based at least in part on performing the dicing procedure, the silicon material with a tape frame; and
bonding, based at least in part on bonding the silicon material with the tape frame, the first memory die of the first memory stack with a first logic die and the third memory die of the second memory stack with a second logic die.

2. The method of claim 1, wherein performing the dicing procedure comprises:
performing a first dielectric dry etching procedure to etch the first dielectric material of the scribe structure;
performing a first plasma dry etching procedure to etch the core silicon material of the scribe structure;
performing a second dielectric dry etching procedure to etch the second dielectric material of the scribe structure; and
performing a second plasma dry etching procedure to etch into the first portion of the silicon material.

3. The method of claim 1, further comprising:
depositing a resistive material over the first memory stack, the second memory stack, and the scribe structure, wherein performing the dicing procedure is based at least in part on depositing the resistive material.

4. The method of claim 3, further comprising:
removing portions of the resistive material that are over the first portion of the scribe structure and the second portion of the scribe structure, wherein performing the dicing procedure into the first portion of the scribe structure and the second portion of the scribe structure is based at least in part on removing the portions of the resistive material.

5. The method of claim 3, further comprising:
removing the resistive material from the first memory die, the second memory die, and the scribe structure, wherein bonding the first memory die to the first logic die and bonding the second memory die to the second logic die is based at least in part on removing the resistive material.

6. The method of claim 1, further comprising:
thinning the silicon material by removing a second portion of the silicon material, wherein the second portion of the silicon material that is removed is based at least in part on a length of the first portion of the silicon material, and wherein bonding the silicon material with the tape frame is based at least in part on thinning the silicon material.

7. The method of claim 6, wherein the second portion of the silicon material is removed using a chemical-mechanical polishing (CMP) procedure, a dry etching procedure, a cleaning procedure, a laser etching procedure, or any combination thereof.

8. The method of claim 1, further comprising:
depositing, based at least in part on performing the dicing procedure, a release material over the first memory stack, over the second memory stack, and over the scribe structure;
depositing an adhesive material over the release material; and
bonding a glass carrier with the adhesive material, wherein bonding the silicon material with the tape frame is based at least in part on bonding the glass carrier with the adhesive material.

9. The method of claim 8, further comprising:
removing the glass carrier, the adhesive material, and the release material based at least in part on bonding the silicon material with the tape frame, wherein bonding the first memory die with the first logic die and bonding the second memory die with the second logic die is based at least in part on removing the glass carrier, the adhesive material, and the release material.

10. The method of claim 9, wherein removing the glass carrier comprises:
performing a laser debonding procedure to debond the glass carrier from the adhesive material.

11. The method of claim 9, wherein the adhesive material and the release material are removed using a cleaning procedure based at least in part on removing the glass carrier.

12. The method of claim 1, further comprising:
bonding a first wafer of memory dies with a second wafer of memory dies to form the first memory stack and the second memory stack, wherein forming the stack is based at least in part on bonding the first wafer with the second wafer.

13. A method for manufacturing a memory device, comprising:
forming a stack comprising a silicon material a first memory stack, a second memory stack, and a scribe structure between the first memory stack and the second memory stack, the first memory stack comprising a first memory die coupled with a second memory die, and the second memory stack comprising a third memory die coupled with a fourth memory die, wherein the stack further comprises a core silicon material between the first memory die and the second memory die, between the third memory die and the fourth memory die, and through a portion of the scribe structure;
bonding, based at least in part on forming the stack, the silicon material with a first glass carrier;
performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and through the silicon material; and
bonding, based at least in part on bonding the silicon material with the first glass carrier, the first memory die of the first memory stack with a first logic die and the third memory die of the second memory stack with a second logic die.

14. The method of claim 13, wherein performing the dicing procedure comprises:
performing a first dielectric dry etching procedure to etch the first dielectric material of the scribe structure;
performing a first plasma dry etching procedure to etch the core silicon material of the scribe structure;
performing a second dielectric dry etching procedure to etch the second dielectric material of the scribe structure; and
performing a second plasma dry etching procedure to etch through the silicon material.

15. The method of claim 13, further comprising:
depositing a release material over the first memory stack, over the second memory stack, and over the scribe structure;
depositing an adhesive material over the release material; and
bonding a second glass carrier with the adhesive material, wherein bonding the silicon material with the first glass carrier is based at least in part on bonding the second glass carrier with the adhesive material.

16. The method of claim 15, further comprising:
de-opaquing the second glass carrier based at least in part on bonding the second glass carrier with the adhesive material.

17. The method of claim 15, further comprising:
removing the second glass carrier, the adhesive material, and second release material based at least in part on bonding the silicon material with the first glass carrier, wherein performing the dicing procedure is based at least in part on removing the second glass carrier, the adhesive material, and the release material.

18. The method of claim 17, wherein removing the second glass carrier comprises:
performing a laser debonding procedure to debond the second glass carrier from the adhesive material.

19. The method of claim 17, wherein the adhesive material and the release material are removed using a cleaning procedure based at least in part on removing the second glass carrier.

20. The method of claim 13, further comprising:
thinning the silicon material by removing a portion of the silicon material, wherein bonding the silicon material with the first glass carrier is based at least in part on thinning the silicon material.

21. The method of claim 20, wherein the portion of the silicon material is removed using a chemical-mechanical polishing (CMP) procedure, a dry etching procedure, a cleaning procedure, a laser etching procedure, or any combination thereof.

22. The method of claim 13, wherein bonding the silicon material with the first glass carrier comprises:
depositing a release material over the silicon material; and
depositing an adhesive material over the release material, wherein the first glass carrier is bonded with the adhesive material.

23. The method of claim 13, further comprising:
depositing a resistive material over the first memory stack, the second memory stack, and the scribe structure, wherein performing the dicing procedure is based at least in part on depositing the resistive material.

24. The method of claim 23, further comprising:
removing portions of the resistive material that are over the first portion of the scribe structure and the second portion of the scribe structure, wherein performing the dicing procedure into the first portion of the scribe structure and the second portion of the scribe structure is based at least in part on removing the portions of the resistive material.

25. The method of claim 23, further comprising:
removing the resistive material from the first memory die, the second memory die, and the scribe structure, wherein bonding the first memory die to the first logic die and bonding the second memory die to the second logic die is based at least in part on removing the resistive material.

26. The method of claim 13, further comprising:
de-opaquing the first glass carrier based at least in part on performing the dicing procedure.

27. The method of claim 13, further comprising:
bonding a first wafer of memory dies with a second wafer of memory dies to form the first memory stack and the second memory stack, wherein forming the stack is based at least in part on bonding the first wafer with the second wafer.

28. A memory device, comprising:
a silicon material comprising a first edge and a second edge, wherein the first edge comprises a first set of scallops and the second edge comprises a second set of scallops;
a first memory die coupled with the silicon material and comprising a first dielectric material, wherein a first width of a first portion of the first dielectric material positioned nearer to the silicon material is greater than a second width of a second portion of the first dielectric material positioned farther away from the silicon material;
a second memory die coupled with the first memory die and comprising a second dielectric material, wherein a third width of a third portion of the second dielectric material positioned nearer to the first memory die is greater than a fourth width of a fourth portion of the second dielectric material positioned farther away from the first memory die; and
a logic die coupled with the second memory die.

29. A product formed by a process of:
forming a stack comprising a silicon material, a first memory stack, a second memory stack, and a scribe structure between the first memory stack and the second memory stack, the first memory stack comprising a first memory die coupled with a second memory die, and the second memory stack comprising a third memory die coupled with a fourth memory die, wherein the stack further comprises a core silicon material between the first memory die and the second memory die, between the third memory die and the fourth memory die, and through the scribe structure;
performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and into a first portion of the silicon material;
bonding, based at least in part on performing the dicing procedure, the silicon material with a tape frame; and
bonding, based at least in part on bonding the silicon material with the tape frame, the first memory die of the first memory stack with a first logic die and the third memory die of the second memory stack with a second logic die.

30. A product formed by a process of:
forming a stack comprising a silicon material a first memory stack, a second memory stack, and a scribe structure between the first memory stack and the second memory stack, the first memory stack comprising a first memory die coupled with a second memory die, and the second memory stack comprising a third memory die coupled with a fourth memory die, wherein the stack further comprises a core silicon material between the first memory die and the second memory die, between the third memory die and the fourth memory die, and through a portion of the scribe structure;
bonding, based at least in part on forming the stack, the silicon material with a first glass carrier;
performing a dicing procedure to etch a first cavity into a first portion of the scribe structure and to etch a second cavity into a second portion of the scribe structure, the first cavity and the second cavity extending through a first dielectric material of the scribe structure, through the core silicon material, through a second dielectric material of the scribe structure, and through the silicon material; and
bonding, based at least in part on bonding the silicon material with the first glass carrier, the first memory die of the first memory stack with a first logic die and the third memory die of the second memory stack with a second logic die.
